(19) United States
(12) Patent Application Publication
(10) Pub. No.: US 2013/0251892 A1
(43) Pub. Date: Sep. 26, 2013

(54) METHOD OF FORMING A WIRING PATTERN

(71) Applicants: Chien-Han Ho, Taipei (TW); Yen-Chih Ho, Taipei (TW)

(72) Inventors: Chien-Han Ho, Taipei (TW); Yen-Chih Ho, Taipei (TW)

(21) Appl. No.: 13/427,213

(22) Filed: Mar. 22, 2012

(51) Int. Cl. H05K 3/10; H05K 3/12

(52) U.S. Cl. 427/98.4

(57) ABSTRACT

A method of forming a wiring pattern is provided. In the method, an adhesive material is coated on a substrate to form an adhesive layer, and then a patterned mask is provided on the adhesive layer, wherein the patterned mask has an opening defining a wiring pattern, and then an electrically conductive paste is filled in the opening, and subsequently the patterned mask is removed so as to form the wiring pattern on the substrate. In the method of the present invention, a wiring pattern is formed by using a screen printing method, but not by using an etching method. As a result, there are no etching contamination issues. Furthermore, the difficulty in etching the finer wiring patterns from the copper foil can be alleviated.

### BACKGROUND OF THE INVENTION

1. Field of the Invention

The present invention relates to a method of forming a wiring pattern, and more particularly to a method of forming a wiring pattern using a screen printing method.

2. The Prior Arts

A printed circuit board usually comprises a wiring pattern that is formed of an electrically conductive material on an insulating material according to the circuit design. In the conventional method, a copper layer is formed on an insulating substrate, and then a desired pattern (for example, a wiring pattern, an alignment hole, a mark, etc.) is formed on the insulating substrate by the photolithography and etching methods.

However, the current legislations for environment protection require that the highly contaminant byproducts formed during the etching process have to be recycled and properly treated, which increases the manufacture cost.

Furthermore, in a chemical etching process, the accurate control of the pH value, temperature, and etching time are required in order to form the desired wiring pattern. Because the chemical etching process is difficult to be controlled, it may inappropriate to be used when the finer wiring patterns are desired to be fabricated. Moreover, the dimension deviation (for example, non-uniform thickness of the layers) can be caused by the etching process, and the dimension deviation becomes larger with the increase of the number of layers. As a result, the alignment holes can not be used for alignment.

### SUMMARY OF THE INVENTION

An objective of the present invention is to provide a method of forming a wiring pattern by using a screen printing method, but not by using an etching method.

In order to achieve the foregoing objective, the present invention provides a method of forming a wiring pattern. According to the present invention, a substrate is provided, and then an adhesive material is coated on the substrate to form an adhesive layer on the substrate, and then a patterned mask is provided on the adhesive layer, wherein the patterned mask has an opening defining a wiring pattern, and then an electrically conductive paste is filled in the opening by the screen printing method, and subsequently, the patterned mask is removed so as to form the wiring pattern on the substrate.

In the method of the present invention, a wiring pattern is formed by using a screen printing method, but not by using an etching method. Consequently, there are no high cost and etching contamination issues. Furthermore, the difficulty in etching the finer wiring patterns from the copper foil can be alleviated.

### BRIEF DESCRIPTION OF THE DRAWINGS

The present invention will be apparent to those skilled in the art by reading the following detailed description of preferred embodiments thereof, with reference to the attached drawings, in which:

FIGS. 1A-1D are schematic views showing processing steps in a method of forming a wiring pattern.

### DETAILED DESCRIPTION OF THE PREFERRED EMBODIMENTS

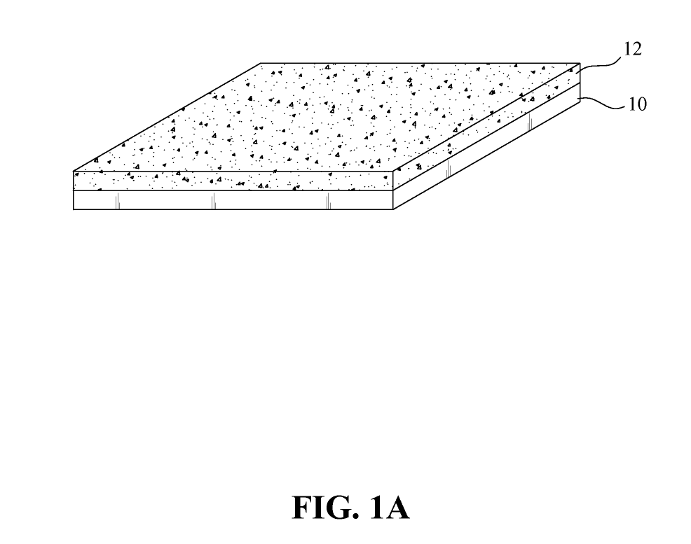

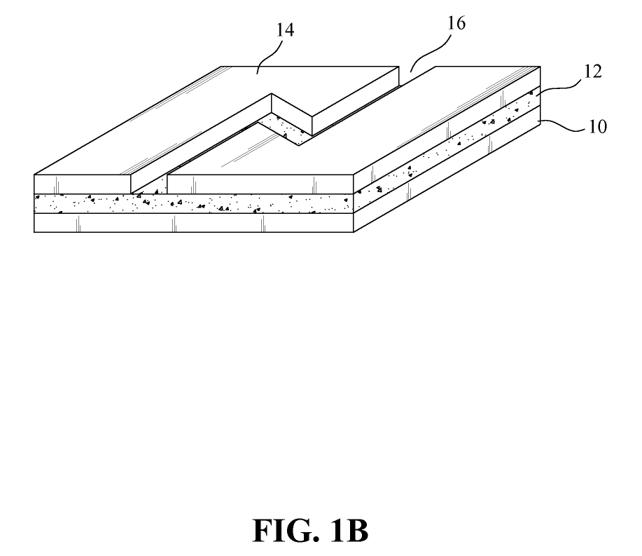

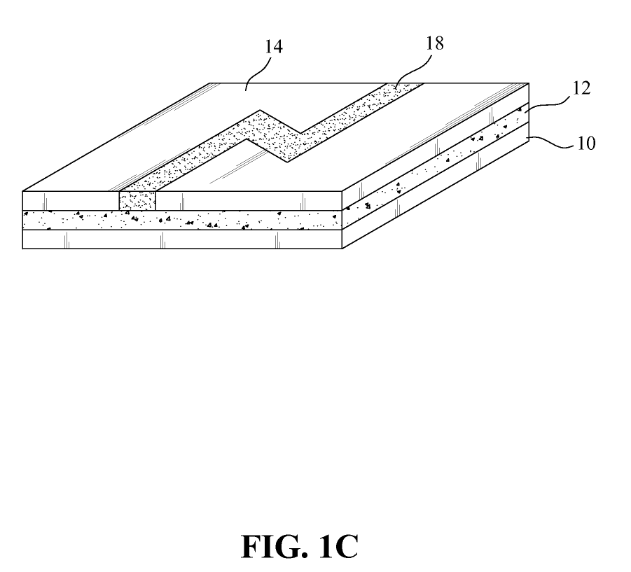

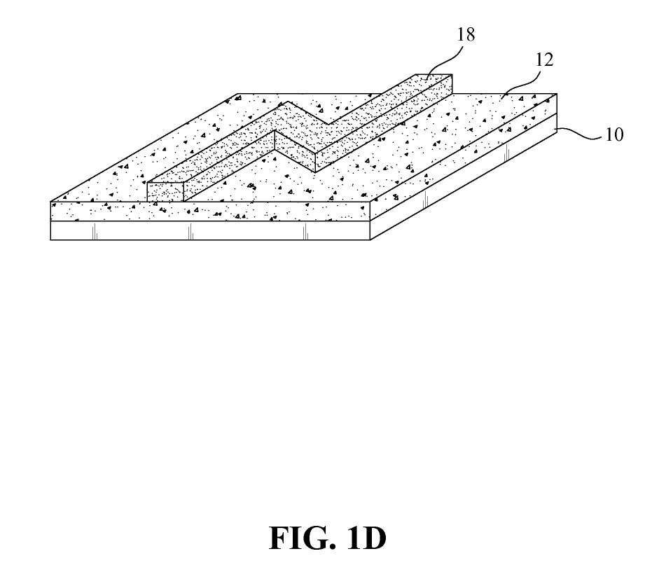

FIGS. 1A-1D are schematic views showing processing steps in a method of forming a wiring pattern according to one embodiment of the present invention.

Referring to FIG. 1A, a substrate 10 is provided. Then, an adhesive material is coated on the substrate 10 to form an adhesive layer 12. As shown in FIG. 1B, a patterned mask 14 is formed on the adhesive layer 12. The patterned mask 14 has an opening 16 which defines a wiring pattern. The patterned mask 14 can be fabricated by forming an opening 16 in an insulating or a metallic plate.

As shown in FIG. 1C, an electrically conductive paste is filled in the opening 16 of the patterned mask 14 by the screen printing method to form the wiring pattern 18 (in other words, the wiring pattern 18 is transferred to the substrate 10 via the patterned mask 14). The electrically conductive paste can be an electrically conductive silver or copper paste.

Finally, as shown in FIG. 1D, the patterned mask 14 is removed.

As described above, in the method of the present invention, a wiring pattern is formed by using a screen printing method, but not by using an etching method. As a result, there are no high cost and etching contamination issues. Furthermore, the difficulty in etching the finer wiring patterns from the copper foil can be alleviated.

The foregoing description is intended to only provide illustrative ways of implementing the present invention, and should not be construed as limitations to the scope of the present invention. While the foregoing is directed to embodiments of the present invention, other and further embodiments of the invention may thus be devised without departing from the basic scope thereof, and the scope thereof is determined by the claims that follow.

What is claimed is:

1. A method of forming a wiring pattern, comprising:
providing a substrate;
coating an adhesive material on the substrate to form an adhesive layer on the substrate;
providing a patterned mask on the adhesive layer, the patterned mask having an opening defining a wiring pattern;
filling an electrically conductive paste in the opening; and
removing the patterned mask so as to form the wiring pattern on the substrate.

2. The method of claim 1, wherein the electrically conductive paste is filled in the opening by a screen printing method.

3. The method of claim 1, wherein the electrically conductive paste is an electrically conductive silver or copper paste.
